(19) United States
(12) Patent Application Publication
(10) Pub. No.: US 2026/0123097 A1
(43) Pub. Date: Apr. 30, 2026

(54) INTERNAL GAIN DEVICES USING MIE SCATTERING AND RESONANCE

(71) Applicant: PixelEXX Systems, Inc., Hinsdale, IL (US)

(72) Inventors: Kenneth Forbes Bradley, Hinsdale, IL (US); Renee Kathryn Carder, Hinsdale, IL (US)

(21) Appl. No.: 19/151,603

(22) PCT Filed: Jul. 15, 2024
(86) PCT No.: PCT/US2024/038071

§ 371 Date: Jul. 28, 2025

Related U.S. Application Data
(60) Provisional application No. 63/513,478, filed on Jul. 13, 2023.

(51) Int. Cl. H10F 77/30; H10F 30/225; H10F 39/10

(52) U.S. Cl. CPC H10F 77/306; H10F 30/225; H10F 39/103; H10F 39/107

(57) ABSTRACT

The devices and methods herein relate to a Mie Avalanche Photodiode (Mie-APD). A Mie-APD leverages Mie resonant scattering and avalanche multiplication to generate current. The Mie-APD features a material layer, an absorption region, and a multiplication region. The multiplication region is configured for multiplying free carriers generated when the absorption region absorbs an electromagnetic perturbation. The material layer serves as a substrate for the absorption region and includes the multiplication region. The structure of the Mie-APD allows for the enhancement of spatial resolution, dynamic range, noise characteristics, and data acquisition speed in applications such as hazard detection, 3D sensing, low light imaging, astronomy, and medical imaging, among others. Variations to the structure, design, and fabrication of the Mie-APD can provide further improved performance and functionality such as enhanced response to specific wavelengths and/or polarizations.

WO

### FIELD OF DISCLOSURE

This disclosure relates generally to photodiodes that use impact ionization to create internal gain to amplify their signal, and, more specifically, photodiodes that use photo sensors harnessing the Mie Effect to amplify performance.

### BACKGROUND

Some conventional semiconductor devices amplify photocurrent by generating free carriers and multiplying these free carriers via avalanche multiplication. However, these traditional devices are unable to provide a high spatial resolution, dynamic range, noise characteristic, and data acquisition speed simultaneously. Indeed, modern conventional avalanche photodiodes (APDs) are restricted by these limitations. In these devices, the photocurrent is amplified using avalanche multiplication under high electric fields within an absorption region (or, in some cases, the absorption region is within the multiplication region), providing a greater number of free carriers for every photon absorbed. Though this is beneficial, these devices are limited by relatively large spatial footprints, higher operating voltages, increased noise characteristics and limited dynamic range. The interplay of these effects lead to an unfortunate compromise between performance and functionality.

As the demands on semiconductor devices evolve, there is a need for an improved avalanche photodiode which overcomes the limitations of existing devices. Achieving high spatial resolution, dynamic range, noise characteristics, and data acquisition speed simultaneously without a reduction in performance or functionality is challenging within the constraints of the traditional device architectures and sizes. As such, creating a device that can achieve this functionality by, for example, leveraging novel device structures to harness non-traditional physical effects would be beneficial.

### SUMMARY

In some aspects, the systems and techniques described herein relate to a Mie resonance avalanche photodiode (“Mie-APD”) including: an absorber including semiconducting material and having a first index of refraction, the semiconducting material including a first doped region at a top surface of the absorber, and the absorber configured to generate free carriers within the semiconducting material in response to an electromagnetic perturbation; a refractive medium surrounding the absorber and having a second index of refraction, the refractive medium and the absorber forming (i) an interface with a boundary index of refraction across the interface that is discontinuous, and (ii) a scattering center configured for generating free carriers via optical absorption and Mie resonance of the electromagnetic perturbation at the scattering center; a multiplier including semiconducting material, the semiconducting material including a second doped region at a top surface of the multiplier that is below a bottom surface of the absorber; a material layer including semiconducting material, wherein the material layer includes the multiplier and a third doped region in the material layer at a bottom surface of the material layer, wherein the first doped region, the second doped region, and the third doped region are doped such that free carriers generated by Mie resonance in the absorber are multiplied to form avalanche carriers via avalanche multiplication in the multiplier; and one or more electrical contacts including a first contact coupled to the absorber and a second contact coupled to the material layer, the one or more electrical contacts configured to sense avalanche carriers generated within the multiplier in response to the electromagnetic perturbation in the absorber.

In some aspects, the systems and techniques described herein relate to a Mie-APD, wherein absorber forms a geometric shape having a set of boundaries, and the scattering center is formed at a geometric boundary of the geometric shape such that the scattering center includes the semiconducting material of the absorber.

In some aspects, the systems and techniques described herein relate to a Mie-APD, wherein absorber forms a geometric shape having a set of boundaries, and the scattering center is formed at the boundaries of the geometric shape such that the scattering center includes a portion of the semiconducting material of the absorber.

In some aspects, the systems and techniques described herein relate to a Mie-APD, wherein the semiconducting material of the absorber, the multiplier, and the material layer is silicon, and the first doped region, the second doped region, and the third doped region include doped silicon.

In some aspects, the systems and techniques described herein relate to a Mie-APD, wherein the absorber has a height of 100 nm and 1000 nm, the height measured in a perpendicular direction relative to the top surface of the material layer.

In some aspects, the systems and techniques described herein relate to a Mie-APD, wherein the absorber has a feature size between 50 nm and 500 nm in a first direction feature size between 50 nm and 500 nm in a second direction, the first direction and the second direction orthogonal to one another and parallel to a top surface of the material layer.

In some aspects, the systems and techniques described herein relate to a Mie-APD, wherein the scattering center is configured to absorb a first wavelength of electromagnetic perturbation, and a size of the scattering center is proportional to the first wavelength of electromagnetic perturbation.

In some aspects, the systems and techniques described herein relate to a Mie-APD, wherein the scattering center is configured to absorb a first polarization of electromagnetic perturbation, and a size of the scattering center is proportional to the first polarization of electromagnetic perturbation.

In some aspects, the systems and techniques described herein relate to a Mie-APD, wherein: the second index of refraction is a complex index of refraction, the multiplier has a third index of refraction, the material layer has a fourth index of refraction, the second index of refraction is less than the first index of refraction, the third index of refraction, and the fourth index of refraction.

In some aspects, the systems and techniques described herein relate to a Mie-APD, wherein the first index of refraction, the third index of refraction, and the fourth index of refraction are a same index of refraction.

In some aspects, the systems and techniques described herein relate to a Mie-APD, wherein the refractive medium is silicon dioxide.

In some aspects, the systems and techniques described herein relate to a Mie-APD, wherein the refractive medium is liquid crystal.

In some aspects, the systems and techniques described herein relate to a Mie-APD, wherein the refractive medium is a low index of refraction material including any of: air, oil, or water.

In some aspects, the systems and techniques described herein relate to a Mie-APD, wherein the first contact and the second contact are Ohmic contacts.

In some aspects, the systems and techniques described herein relate to a Mie-APD, wherein the second doped region extends beyond a geometric boundary of the absorber.

In some aspects, the systems and techniques described herein relate to a Mie-APD, further including a beveled edge between the top surface of the material layer and a side surface of the absorber.

In some aspects, the systems and techniques described herein relate to a Mie-APD, wherein the first doped region and the second doped region are a same type of doping, and the third doping region is a different type doping than the same type of doping.

In some aspects, the systems and techniques described herein relate to a Mie-APD, wherein the first doped region has a higher doping density than the second doped region.

In some aspects, the systems and techniques described herein relate to a Mie-APD, wherein the Mie-APD is a Mie-APD in an array of Mie-APDs forming a Mie Silicon Photomultiplier.

In some aspects, the systems and techniques described herein relate to a Mie-APD, wherein the Mie-APD is a Mie-APD in an array of Mie-APDs forming a Mie Single Photon Avalanche Diode.

### BRIEF DESCRIPTION OF DRAWINGS

FIG. 1 illustrates a prior art representation of an avalanche photodiode, according to an example embodiment.

FIG. 2 illustrates a Mie photo sensor, according to an example embodiment.

FIG. 3A illustrates an absorption energy spectra plot for Mie devices with different dimensions, according to an example embodiment.

FIG. 3B illustrates a current generation plot for Mie devices with different dimensions, according to an example embodiment.

FIG. 3C illustrates an absorption energy spectra plot for Mie devices with different dimensions, according to an example embodiment.

FIG. 4 illustrates a Mie Avalanche Photodiode (“Mie-APD”), according to an example embodiment.

FIG. 5A illustrates a cross-sectional doping diagram of a Mie-APD, according to an example embodiment.

FIG. 5B illustrates a doping profile of a Mie APD, according to an example embodiment.

FIG. 6A illustrates a cross-sectional electrical-field diagram of a Mie-APD, according to an example embodiment.

FIG. 6B illustrates an electric field profile of a Mie APD, according to an example embodiment.

FIG. 7A a cross-sectional doping diagram of a Mie-APD configured to reduce electric field hotspots, according to an example embodiment.

FIG. 7B illustrates a cross-sectional electrical-field diagram of a Mie-APD configured to reduce electric field hotspots, according to an example embodiment.

FIG. 8 illustrates a breakdown voltage plot for a Mie-APD, according to an example embodiment.

FIG. 9 illustrates an example circuit diagram for a Mie-SPAD, according to an example embodiment.

The figures depict various embodiments for purposes of illustration only. One skilled in the art will readily recognize from the following discussion that alternative embodiments of the structures and methods illustrated herein may be employed without departing from the principles described herein.

### DETAILED DESCRIPTION

### I. Introduction

Common to many low light applications is the growing demand for larger imaging and detection arrays to enhance spatial resolution, dynamic range, data acquisition speed, and overall functionality. Typically, low-light, larger-format pictures requires 1D or 2D scanning, thereby curtailing the frame rate, which is limited by the speed of the scanner. In addition, scanners may be bulky and add another level of complexity to the imaging system. The growing demands on compact and high-definition arrays have motivated the exploration of pixel miniaturization techniques to achieve sub-10 μm pixels. That said, the crux of a large-format camera remains the pixel pitch and the amount of functionality per pixel. Unfortunately, scaling these specialized pixels has an impact on key performance metrics.

Backside illumination, 3D integration or stacked architectures (control, processing, and readout electronics are on a different wafer(s)), and well-sharing can improve performance by increasing the area of the sensor that is light sensitive and directing more light to converge on that sensitive area, but reducing pixel pitch remains significantly behind that of CMOS image sensors and can introduce many deleterious effects as set forth below. As such, a device that harnesses Mie Scattering and Mie Resonance that enables a device to replace these deficient semiconductor devices is described hereinbelow.

### II. Avalanche Photodiodes

### Operation

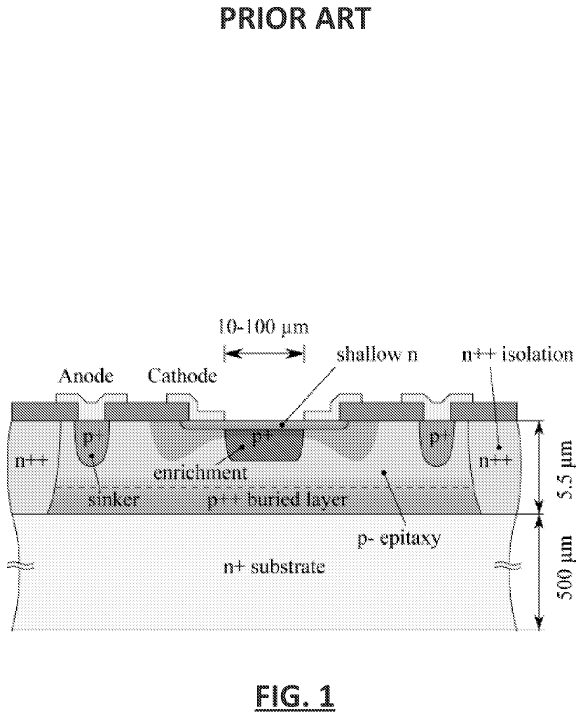

An avalanche photodiode (APD) is a specialized semiconductor device designed to exploit the phenomenon of avalanche breakdown. For reference, FIG. 1 illustrates a prior art representation of an avalanche photodiode, according to an example embodiment.

Typically, an APD is constructed from a material with a wide bandgap, often silicon or germanium. The APD typically features several layers including one or more p-n junctions. Within this layered structure, an intrinsic region is positioned between a p region and an n region. Within the intrinsic region, carriers achieve “avalanche breakdown” due to the region's extremely high electric field-which gives rise to the multiplication effect.

In more detail, the APD's structure usually commences with a substrate layer, followed by a heavily doped n+ layer (or p+ layer, depending on the configuration). Overlying this layer is a lightly doped n− layer forming the depletion region. Above that is a p type layer, and capping off the stack is a heavily doped p+ layer, forming an ohmic contact. Around the periphery of the device, p+ isolation rings may be present to avoid premature edge breakdown. As mentioned, at the heart of the device lies the intrinsic region, where, under reverse bias conditions, electron-hole pairs created by incoming photons are rapidly accelerated by the intense electric field, leading to the notable avalanche breakdown phenomenon. Traditional structures are oftentimes horizontally oriented to grant a larger absorption region but can sometimes be vertically oriented with worsened performance.

An APD's functioning can be divided into three operating zones—low voltage mode, reverse bias mode, and Geiger mode—based on the applied voltage.

In low voltage mode, an APD operates in the photodiode regime. In this regime, carriers generated via optical absorption (e.g., electron hole pairs) do not experience internal multiplication of carrier. In this case, the current measured is directly proportional to light intensity.

In reverse bias mode, an APD operates in the avalanche breakdown regime. As the applied reverse voltage increases, the electric field within the diode also intensifies. Electrons generated by optical absorption gain vitality and produce secondary electron-hole pairs through impact ionization, leading to linear or proportional mode operation. A unique characteristic of this mode is that only electrons can stimulate secondary pair generation. The diode allows for gain ranging from tens to hundreds, and the extracted current is proportional to the number of detected photons, making the avalanche self-quenching.

In Geiger mode, an APD operates in the avalanche breakdown regime—but with additional multiple multiplication. In this mode, even holes gain enough velocity for secondary electron-hole pair generation. Consequently, a self-sustaining avalanche initiates a fast-rising current marking the photon's arrival time at the device with high precision. The avalanche is then quenched by reducing the bias voltage through a specific ‘quenching circuit,’ required to prepare the diode for subsequent photon detection. Geiger mode is the mode typically associated with Single Photon Avalanche Diodes (SPAD) used in Silicon Photomultipliers (SiPMs).

To control these modes and their operation, the device structure of the APD is configured to manipulate the electric fields around the device (e.g., differential doping patterns, guard rings, relative region sizes, etc.). Overall, the device is structured to manage photogenerated charge and prevent inadvertent current injection and potential disruptions. Such arrangements help single out parasitic devices, noise, Electrostatic Discharge (ESD) failure, and latch-up.

Finally, configurations of avalanche photodiodes or SPADs can vary to cater to different needs in low-light imaging and detection. Each diode can be linked to independent sensing electronics to represent a single pixel in the array, or multiple diodes can share common processing electronics to form a detector, known as analog or digital silicon photomultipliers or photon-to-digital counters.

### Applications

Different types of avalanche photodiodes are used in applications where low light levels must be measured with precision, addressing challenges of sensing, timing, and quantifying low-light signals down to the single-photon level. The demands in both low-light imaging and 3D-sensing, along with the convergence of new architectures and optics are expanding market opportunities.

As an example, the demand for silicon photomultipliers is expected to witness considerable growth as they offer significant advantages over photomultiplier tubes, the dominant incumbent technology. Some of the advantages of SiPMs are low cost, robust construction, excellent response time, compactness, improved life span, lower power consumption, lower operating voltages, and immunity to magnetic fields.

### Disadvantages and Detriments

As described above, APDs are used in both Single-Photon Avalanche Diodes (SPADs) and Silicon Photomultipliers (SiPMs). These devices often employ a specific pixel structure configured for increasing the performance and reliability of those structures. However, their typical structure includes various characteristics that provide limitations to performance such as, e.g., geometric attributes, absorption, and signal conversion characteristics. These limitations, when taken in aggregate, determine the devices overall characteristics such as, e.g., the observable signal intensity range. Optimizing one of these attributes tends to inadvertently affect the others unfavorably, and this interdependence becomes more pronounced upon pixel miniaturization.

To illustrate, the efficiency of photon detection in APD based devices is dictated by several intrinsic and external factors. Paramount among these are the quantum efficiency of the device and the proportional area sensitive to light. Surface reflection losses, active volume and absorption length, and the Geiger breakdown probability and associated recovery times further impact the overall performance. As the cross-sectional area of the pixel decreases, a reduction of signal strength is also observed due to the laws governing geometric optics. Additionally, these pixels tend to operate at higher voltages compared to standard photodetectors, thereby necessitating guard-ring structures to avoid false positive signals. Some devices elect to add a one or more filters and/or other optical elements (e.g., wavelength, polarization, etc.) to add wavelength and/or polarization selectivity, but filtering solutions become untenable at lower device sizes and/or with low light conditions. Overall, regrettably, these traditional structures consume considerable pixel area leading to a consequent reduction in the signal.

Oftentimes, APD based devices maintain a constant sensor depth, even as the sensor area decreases, to ensure the desired photon absorption probability (which impacts fabrication difficulty negatively). The balancing act between depth and area compels an increase in the sensor's aspect ratio to sustain a fixed absorption probability. However, with the sensor area diminution comes the essential reduction of pixel-to-pixel spacing, reduction in red (an longer wavelength) signals, etc., which makes the fabrication of optical isolation structures increasingly difficult. Devices as they currently exist have an absorption region that is at least 1 μm deep to facilitate effective photon absorption. Moreover, the introduction of smaller pixel areas presents significant challenges in intricately doping pixels with internal gain.

Additionally, compared to their conventional counterparts, avalanche diodes experience higher dark currents and signal noise that can undermine the detection of weak signals under low-light conditions. Various device metrics (e.g., size, shape, aspect ratio, etc.) impact the amplification capabilities of such diodes and their produced signal—including noise at high gain levels. Thus, devices are optimized for amplification (e.g., by geometry and doping selections), the device is also amplifying noise (especially at high gain levels). This phenomenon leads to a degradation of signal quality as the noise levels increase.

Temporal constraints further limit the APDs. The period between the avalanche occurrence and the subsequent recovery phase creates a temporal detection limit within which additional signals cannot be registered. This period, the dead time, imposes an upper limit on the maximum measurable light intensity. When considering array configurations, devices are configured to account for the additional area required for both the component isolation, as well as the electronic components necessary for sensor operation and data gathering. Photons that incidentally impact these auxiliary areas can't be measured, leading to decreased measurement sensitivity. An additional challenge arises from interpixel crosstalk, which inflates the photon counts and disrupts spatial information. In other words, the necessarily large areas of “protective” material surrounding arrays, decreases the spatial detection capabilities of traditional APD structures.

Lastly, the functioning of avalanche diodes can become saturated under high light conditions due to the internal gain, which constrains their dynamic range. Saturation impacts the recovery time, again presenting an upper limit on light intensity measurement. Geiger mode operation, while enabling the detection of a single photon, does not provide any information on the quantity of photons within that signal. Although smaller pixel sizes can potentially reduce the chances of multiple photons impacting the same pixel, it does little to address the broad array of issues listed above.

### III. Mie Effect in Photo Absorbers and Sensors

Devices that leverage Mie scattering and Mie resonance can lead to reduced features sizes to traditional semiconductor devices that rely on optical absorption of light to generate carriers.

Mie scattering, a relatively obscure (until recently) general solution to Maxwell's equations, can be described, at a high level, as light scattering from an object. The Mie scattering solution becomes particularly complex when the size of the object (e.g., one or more of its dimensions) is in a specific range relative to the wavelength of light being scattered (λ). The effects are particularly pronounced with the object size is about ⅕λ to about 10λ. Semiconductor devices can harness these effects and capitalize on the scattering characteristics to generate signals by creating substantial fields within the devices. In effect, Mie scattering causes a device with a relatively small profile to have an optical cross section greater than its small profile, which leads to enhanced internal fields and carrier generation. The enhanced carrier generation, understandably, has many potential benefits in semiconductor devices.

Semiconductor based Mie photo sensors, for instance, can demonstrate distinct, advantageous differences relative to their conventional counterparts. A key differential lies in the thickness requirement in the Mie photo sensor, which is substantially reduced because the Mie photo sensors can concentrate fields in structures that are thinner than expected (relative to conventional photo sensors). Moreover, unlike conventional sensors that leverage thickness to maximize light absorption probability, Mie sensors tend to concentrate leftover energy internally while keeping both scattered and absorbed components of the incident energy minimal.

Additionally, devices that harness Mie scattering effects (e.g., Mie photo sensors) can bear scattering centers composed of dielectric materials with a refractive index that is considerably mismatched with their surroundings, producing a lower-than-expected attenuation coefficient. This design characteristic allows for large internal electric and magnetic fields in response to incident light, thus driving substantial free carrier creation-an essential factor for generating far-field Mie scattering patterns.

Still further, devices that enable Mie scattering and resonance have an optical cross-section that is larger than their physical cross section. That is, a Mie photo sensor (or some other Mie-enabling device) absorbs light as if it has a larger area than its physical size. Thus, Mie enabling devices enable device geometries that were heretofore thought impossible. For instance, a Mie Photo Sensor is able to efficiently absorb light with a geometry that is approximately the same as the wavelength absorbed (whereas conventional devices require much larger device geometries than the wavelength).

In terms of application, these Mie scattering's distinct resonance-creation characteristics enable the design of sensors sensitive to specific wavelengths and specific polarizations without the need for wavelength or polarization filtering. By adjusting parameters such as the scattering object size (e.g., various critical dimensions), scattering center material, dielectric material, etc., a wide or narrow wavelength response can be achieved as per requirement. Further, shaping and sizing can be employed intentionally to create wavelength or polarization selectivity in these sensors. For instance, a rectangular pillar shaped device may select different wavelengths and/or polarizations than a cylindrical pillar shaped device.

This wavelength and polarization selectivity can be found in the underlying mathematics of Mie scattering, which is not discussed herein. Briefly however, solutions to Mie scattering are generally derived from an expansion of the electromagnetic field in terms of infinite orthonormal functions to comply with the boundary conditions at the scattering object surface. Thus, factors such as object shape and size, light wavelength, index of refraction, and order of the expansion predominantly affect these coefficients in the computation. These coefficients indicate the resulting intensity of the electric and magnetic fields within the scattering object, which thereby influence the total electric or magnetic response of the device.

Therefore, overall, semiconductor devices that leverage Mie scattering (e.g., via the selection of scattering center shape, size, etc.) are able to outperform their traditional semiconductor counterparts. This stems from several key factors. First, Mie scattering devices capitalize on scattering characteristics to create substantial in-particle fields, driving large free carrier creation-a major factor for generating significant photocurrent and enhancing, e.g., image generation characteristics. This is a far cry from conventional sensors where energy is often concentrated externally which limits their efficiency. Second, while conventional detectors rely on increasing their thickness to maximize light absorption probability, Mie detectors can achieve high field concentration in thinner structures. This represents a significant practical advantage as it eliminates stringent thickness requirements. Third, Mie detectors can be designed to respond sensitively to specific wavelengths of light without needing to filter the light for a particular wavelength, providing inherent wavelength specificity. This opens the door to highly advanced applications, like multispectral imaging that conventional semiconductor counterparts might struggle to accomplish. Fourth, Mie devices have an optical cross-section that is greater than its physical cross-section. This enables many devices to achieve smaller device sizes, without experiencing many of the traditional deleterious effects that manifest with those smaller sizes. Finally, by intelligently adjusting sensor parameters, Mie detectors exhibit remarkable flexibility in achieving both wide and narrow wavelength response, allowing them to be finely tuned for a broad array of applications.

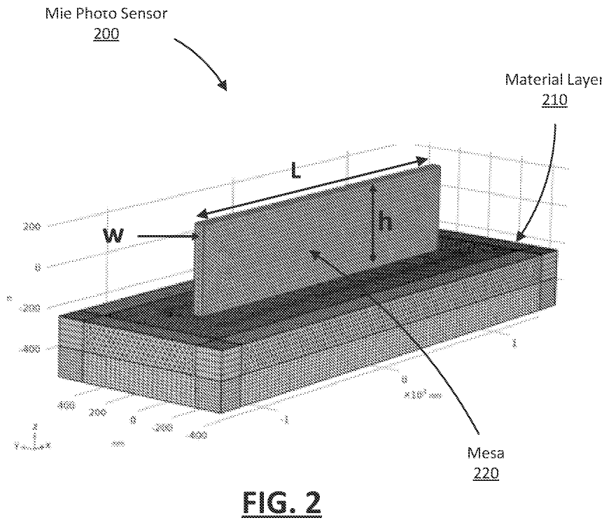

To provide context, FIG. 2 illustrates a Mie photo sensor, according to an example embodiment. The Mie photo sensor 200 includes a material layer 210 and a mesa 220. As illustrated, the mesa 220 has a length greater than its width, and a height greater than the width but less than the length. Other dimensions, shapes, and sizes are also possible. The mesa 220 is positioned on top of, and attached (or coupled) to, the material layer 210. Here, the mesa 220 is an example of a scattering center that enables Mie scattering effects.

In this example, the mesa 220 is formed by growing a layer of a first semiconducting material on top of the material layer 210, which is a second semiconducting material. The first semiconducting material and the second semiconducting material may be the same or different depending on the configuration of the device. For instance, one first semiconducting material may be gallium arsenide while the second semiconducting material may be silicon or doped silicon. In another example, both the first semiconducting material and the second semiconducting material may be silicon.

The structure of the Mie photo sensor 200 can be defined using traditional semiconductor lithography techniques. For instance, a combination of photo-resist application, photo-resist patterning with optical lithography and/or electron-beam lithography, and etching can be utilized to fabricate the Mie photo sensor. In this way, the fabrication process can remove defined portions of the n-type gallium arsenide leaving behind individual mesas. Subsequent processing steps can create contacts to the Mie photo sensor 200 (not pictured). The contacts can be ohmic, Schottky, p-n, p-i-n, etc., and the device may have conducting areas to electrically access the contacts.

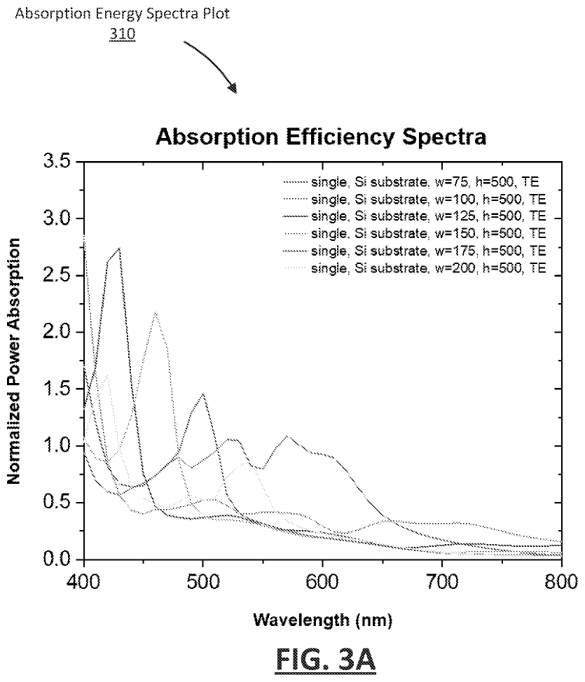

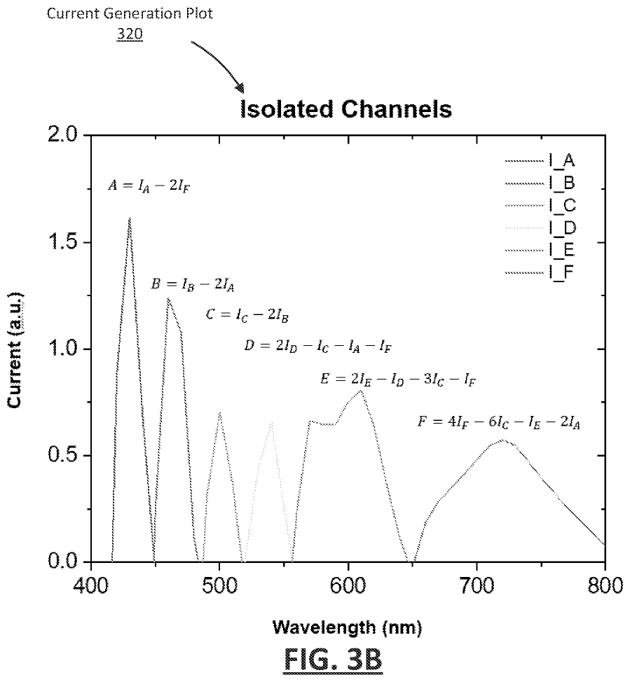

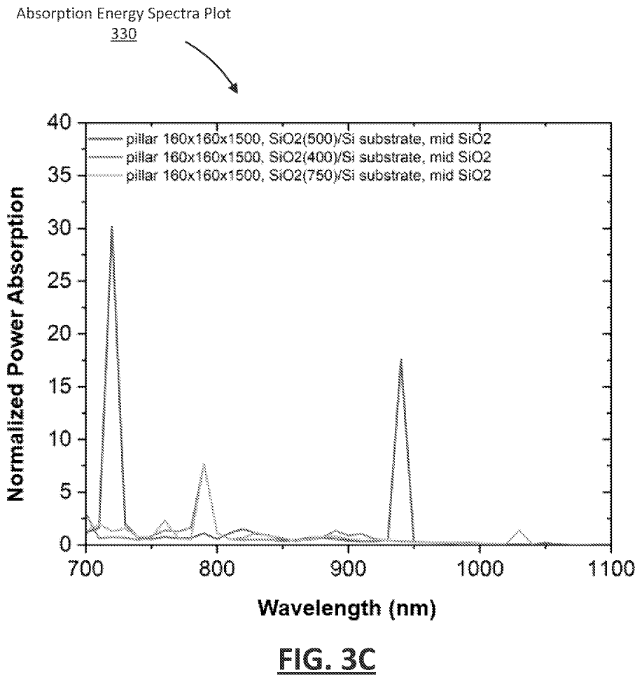

FIG. 3A-3C illustrate various characteristics of devices that utilize Mie scattering.

FIG. 3A illustrates an absorption energy spectra plot for Mie devices with different dimensions, according to an example embodiment. In the absorption energy spectra plot 310, the x-axis is wavelength, and the y-axis is the normalized power absorption. Each line in the plot represents the absorption spectra of a different device as the width of the device varies from 75 nm to 200 nm. The length and height are constant at 500 nm for each device. The polarization of the incident is constant for each device. As illustrated, different size devices absorb different wavelengths of light at different efficiencies.

FIG. 3B illustrates a current generation plot for Mie devices with different dimensions, according to an example embodiment. In the current generation plot, 320 the x-axis is wavelength, and the y-axis is current. Each line in the represents current generated by a device when exposed to a wavelength corresponding to its peak absorption. So, for instance, for a device having peak absorption at 500 nm, the current generation plot shows the current generated by that device when exposed to 500 nm light. Again, each line in the plot represents the absorption spectra of a different device as the width of the device varies from 75 nm to 200 nm. The length and height are constant at 500 nm for each device. The polarization of the incident is constant for each device.

FIG. 3C illustrates an absorption energy spectra plot for Mie devices with different dimensions, according to an example embodiment. In the absorption energy spectra plot 330, the x-axis is wavelength, and the y-axis is the normalized power absorption. Each line in the plot represents the absorption spectra of a different device as the thickness of the material layer varies from 400 to 750 nm. The width, height, and length are constant at 160 nm, 160 nm, and 1500 nm, respectively, across all devices. The polarization of the incident is constant for each device. As illustrated, different size devices absorb different wavelengths of light at different efficiencies.

### IV. Mie Avalanche Photo-Detectors

### Introduction

Until now, efforts to shrink pixels that utilize internal gain have suggested there is a size floor of 2.0 microns, and that pixels cannot be reduced below this size without significant impact on performance metrics. In traditional APD based devices (e.g., SPADs), this limitation is due to the required device depth-to-area ratio and the difficulty of doping such a device. It is also due to the presence of internally generated charges that trigger false positive events, a problem that increases as the pixel size shrinks. APD arrays (e.g., SPADs and SiPMs) also suffer from the problem that a shrinking proportion of the array surface acts as active sensor.

Accordingly, a device that utilizes Mie-resonant light absorption and features of APDS (and SPADs) allows for smaller scale APD devices. These smaller scale devices provide a unique path forward to reduce pixel size using internal gain. This internal gain enables many benefits that correspond to pixels with a larger footprint but does so without the negative impacts on key performance metrics that comes with increased size (e.g., spatial resolution, power requirements).

### Operation and Structure

A semiconductor device that leverages Mie resonant scattering and avalanche multiplication to generate current is described (a “Mie-APD”). Mie-APDs can be leveraged to create Mie Scattering Single Photon Avalanche Diodes (a “Mie-SPAD”), which can be used in Mie Scattering Silicon Photomultipliers (a “Mie-SiPM”). Array devices are described in more detail below.

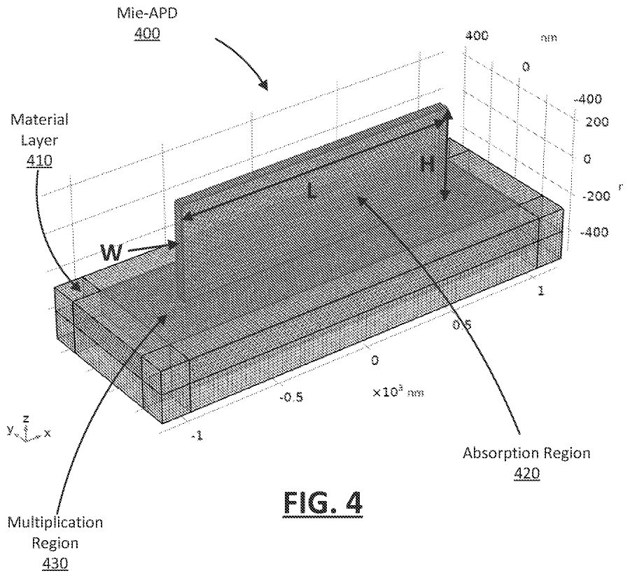

FIG. 4 illustrates a Mie-APD, according to an example embodiment. The Mie-APD 400 includes a material layer 410, an absorption region 420 (e.g., an “absorber”), and a multiplication region 430 (e.g., a multiplier). At a high level, the material layer 410 includes the multiplication region 430. The multiplication region 430 is configured for multiplying free carriers generated when the absorption region 420 absorbs an electromagnetic perturbation (e.g., an incident photon). Contacts to the Mie-APD 400 measure generated and multiplied carriers.

Providing more detail, the Mie-APD 400 includes a material layer 410. The material layer 410 is typically a layer, region, or volume of semiconducting material. For instance, the material layer may be a silicon or germanium substrate. In other configurations, the material layer 410 may be any of Si, Ge, GaN, GaAs, InAs, InGaAs, GaN, SiC. The material layer has a material layer index of refraction and a material layer doping level. The index of refraction may be 2.4 to 4.2 and the doping level may be intrinsic to just below degenerate. The doping level may vary across the material layer as outlined below.

The material layer 410 has a top surface that abuts a refractive medium (not shown) and a bottom surface to which one or more electrical contacts can be made. The material layer 410 has one or more internal surfaces that abut the internal surfaces of the multiplication region 430 (see below). That is, the material layer 410 may be configured such that the multiplication region 430 is internal to the material layer 410.

The material layer 410 may include one or more isolation regions (not shown). The isolation regions serve to isolate the absorption region 420 and/or the multiplication region 420 from other Mie-APDs in a Mie-APD array (e.g., such as a Mie-SPAD or Mie-SiPM). The isolation regions may be SiO₂, Al₂O₃, BN (boron nitride), Si₃N.

The Mie-APD 400 includes an absorption region 420. The absorption region 420 defines an electromagnetic scattering center of the Mie-APD 400. The scattering center is the area of the Mie-APD configured to generate free carriers via optical absorption and Mie resonance of an electromagnetic perturbation. That is, the absorption region 420 is where an electromagnetic perturbation (e.g., a photon) is absorbed and converted into free carriers via Mie resonance. As described above, the optical absorption and carrier creation is enhanced relative to the footprint of the absorption region 420 due to Mie resonance.

To provide additional context to the scattering center, it can be defined in different ways. For example, the scattering center can be defined as a geometric object (e.g., the absorber) surrounded by a refractive medium. As the absorption region 420 has a first index of refraction and the refractive medium has a second index of refraction, a complex, discontinuous index of refraction is formed at an interface between the absorption region and the index of refraction. The scattering center, therefore, is the area of semiconducting material confined within the geometric boundaries of that complex, discontinuous index of refraction. In some cases, the scattering center may be a portion of the geometrically bounded semiconducting material rather than the entire region of the geometrically bounded semiconducting material. Additionally, when stated in a different manner, the scattering center of the Mie-APD is the semiconducting material (or some portion thereof) of the absorption region 420 bounded by the refractive medium.

The absorption region 420, in the illustrated example, is positioned on top of, and attached (or coupled) to, the multiplication region 430. In other words, the absorption region 420 has a top surface that abuts a refractive medium (not shown), a bottom surface that abuts the multiplication region 430 and/or material layer 410, and one or more side surfaces that abut the refractive medium. Additionally, the absorption region 420 is similarly shaped to a mesa of a Mie Photo Sensor (e.g., mesa 220). That is, absorption region 420 is typically a layer, region, or volume of semiconducting material. In the illustrated example, the absorption region 420 has a length greater than its width, and a height greater than the width but less than the length. Other dimensions, shapes, and sizes are also possible. More broadly, the absorption region forms a geometric shape having a set of boundaries.

Importantly, a Mie-APD enables smaller device geometries than traditional APDs. To that end, the length may be between 25 nm-600 nm, the width may be between 25 nm-600 nm, and the height may be between 0.1 micron-2 micron. Additionally, the absorption region 420 may be a silicon or germanium layer. In other configurations, the absorption region 420 may be any of Si, Ge, GaN, GaAs, InAs, InGaAs, GaN, SiC. The absorption region has an absorption region index of refraction and an absorption region doping level. The index of refraction may be 2.4 to 4.2 and the doping level may be intrinsic to just below degenerate. The doping level may vary across the absorption region as outlined below.

Notably, recall that in traditional APD devices, mesa style absorption regions do not exist. Instead, these systems include a thickness of semiconductor materials that act as an absorbing medium and, at one or more locations a differentially doped semiconductor to establish a depletion region for absorption. The depletion regions drive collection of the locally generated, photo-produced, charges (e.g., the “shallow n” in FIG. 1). However, shrinking a traditional APDs dimensions so that individual pixels are smaller than the incident light's wavelength does not yield improved performance (as described above) and create a Mie-APD. Further, shrinking the thickness of the APDs so that it is optically thin does not create a Mie-APD (as described above). Furthermore, generally, individual conventional APDs are surrounded by additional semiconductor materials that support the signal collection electronics or isolate the collection area. Upon reducing the photoactive region of the traditional APD to dimensions of a Mie-APD, this additional material in combination with the photoactive region forms a larger structure that does not define a discreet dielectric scattering center as is required for Mie-APDs.

The shape and relative dimensions of the absorption region 420 affect generation of free carriers using Mie Resonance. In some cases, the ratios between these measurements may be configured to select for particular wavelengths and/or polarizations of incident light. For instance, the absorption region 420 may absorb and resonate light with a wavelength that is a multiple of one or more of the major dimensions (e.g., length, height, width), a multiple of an area formed by two of the major dimensions, a multiple of a volume formed by three of the major dimensions, etc. The exact formulation of these multiples is grounded in the particular Mie solution to Maxwell's Equation for the object and the wavelength of the absorbed electromagnetic perturbation.

As an example, consider a cuboid silicon mesa (e.g., an absorption region 420) on a silicon substrate (e.g., a material layer 410). The mesa has a horizontal cross section of 60 nm by 60 nm and a height of 600 nm. The mesa has a single absorption peak for light centered at 450 nm (but does not have any other resonance peaks). In addition, the absorbed photon energy for light with normal incidence is equivalent to the photon energy incident on a surface of 136.8μ². In other words, the optical cross section of the mesa is 38 times larger than the physical cross section. For mesas with 80 nm×80 nm cross sections that are 1.5 μm high, this ratio of optical cross section to physical cross section remains the same, but the absorption peak shifts to approximately 540 nm.

As another example, a silicon ridge shaped mesa (e.g., an absorption region 420) with horizontal cross sections of 50 nm×2000 nm, and a height of 450 nm, on a silicon substrate (e.g., a material layer 410) has an optical to physical cross section ratio of 4.5 for transverse magnetic polarized light (electric field parallel to the long direction of the ridge) having a wavelength of 460 nm but a cross section ratio of approximately 1 for transverse electric polarized light of the same wavelength.

In other words, the scattering center of a shape of a Mie-APD may be configured (e.g., selecting length, width, height, aspect ratio, etc.) to absorb a first wavelength of electromagnetic perturbation. That is, the size of the scattering center is proportional to the first wavelength of electromagnetic perturbation. Similarly, a shape of a Mie-APD may be configured (e.g., selecting length, width, height, aspect ratio, etc.) to absorb a first polarization of electromagnetic perturbation. That is, the size of the scattering center is proportional to the first wavelength of electromagnetic perturbation. Again, the actual proportionality is based on the solution the Mie scattering solution for the device at plat.

The absorption region 420 may be formed by growing a layer of a first semiconducting material on top of the multiplication region 430, which is a second semiconducting material. The first semiconducting material and the second semiconducting material may be the same or different depending on the configuration of the device. For instance, one first semiconducting material may be gallium arsenide while the second semiconducting material may be silicon or doped silicon. In another example, both the first semiconducting material and the second semiconducting material may be silicon. The semiconducting materials may be other materials such as, e.g., Si, Ge, GaN, GaAs, InAs, InGaAs, GaN, and SiC. The absorption region 420 has an absorption region index of refraction and an abortion region doping level. The index of refraction may be 2.4 to 4.2 The doping level may vary across the absorption region as outlined below.

The absorption region 420 (and material layer 410, and multiplication region 430) is surrounded by a refractive medium (not pictured). The refractive medium abuts the absorption region and forms an interface. The index of refraction across the interface that is complex and/or discontinuous, attributing to the Mie effects in the absorption region 420. The refractive medium can be many different materials. For instance, the refractive medium may be, e.g., silicon dioxide, a liquid crystal, a low index of refraction material such as air, oil or water, Al₂O₃, BN (boron nitride), Si₃N, or other insulating or semi-insulating materials with index of refraction less than that of the absorption region, etc. In some cases, the refractive medium may have a complex index of refraction.

The Mie-APD 400 includes a multiplication region 430. The multiplication region 430 is an area in the Mie-APD 400 where free carriers generated by optical absorption in the absorption region 420 experience avalanche multiplication effects. As described in greater detail below, a drift field established in the absorption region causes the generated carriers to propagate towards the multiplication region 430, and an ionization field in the multiplication region 430 causes the generated carriers to multiply using avalanche effects as described above.

As illustrated, the multiplication region 430 is contained within the material layer 410 and is positioned below the absorption region 420. That is, a top surface of the multiplication region 430 is positioned beneath and is attached to (or connects to) the absorption region 420. The side surfaces and bottom surface of the multiplication region 430 abut the material layer 410 in which it resides. In other words, the side surfaces of the multiplication region 430 is an internal surface that abuts internal surfaces of the material layer 410.

Notably, the illustrated multiplication region 430 is given boundaries largely for demonstrative purposes. The multiplication region 430, more generally, is the region within the material layer 410 configured such that free carriers experience avalanche multiplication. As described in more depth below, this is oftentimes due to the doping profile and resulting electric field internal to the material layer 410. In other words, the multiplication region 430 may be considered a layer, region, or volume of the material layer 410 with a different doping profile, where that doping profile is configured to enable an electric field that induces avalanche multiplication.

Thus, overall, the multiplication region 430 can also be made of a material, have an index of refraction, and can include a doping profile. Oftentimes, the semiconducting material of the multiplication region 430 is the same semiconducting material as the material layer 410, but they can be different. Similarly, the index of refraction of the multiplication region 430 is the same index of refraction as the material layer 410, but they can be different. The doping profile of the multiplication region is discussed in more detail below.

The Mie-APD 400 includes one or more electrical contacts (not shown). The electrical contacts may be used to induce one or more electromagnetic states in a Mie-APD 400. For instance, the one or more electrical contacts may be used to generate an electrical field (e.g., diffusion field, ionization field) internal to the Mie-APD 400 (by biasing the Mie-APD 400) or drive a current in the Mie-APD 400. Moreover, the one or more electrical contacts may be configured to measure one or more electrical or magnetic characteristics. For instance, the one or more electrical contacts may be configured to measure a voltage across the Mie-APD 400 or a photocurrent generated by the Mie-APD.

The one or more electrical contacts can be differently positioned depending on the configuration of the Mie-APD 400. For instance, one or more of the electrical contacts can be on a top surface of the absorption region 420, on a top surface of the multiplication region 430, on a top surface of the material layer 410, on a bottom surface of the material layer 410, etc. Additionally, the one or more electrical contacts may be different types of contacts. For instance, the electrical contacts may be ohmic, Schottky, p-n, p-i-n, etc., and the Mie-APD 400 may have conducting areas to electrically access the contacts. In some cases, the one or more electrical contacts may be capacitively or electrostatically coupled to the Mie-APD 400 (rather than being directly coupled to the Mie-APD 400).

The Mie-APD 400 also has a unique doping structure. The doping structure, like that of a traditional APD, is configured to generate a drift field in the absorption region 420 and an ionization field in the multiplication region 430. In general, there are three doping regions within a Mie-APD: (1) a first doping region near a top surface of the absorption region 420, (2) a second doping region near a top surface of the multiplication region 430, and a third doping region near a bottom surface of the multiplication region.

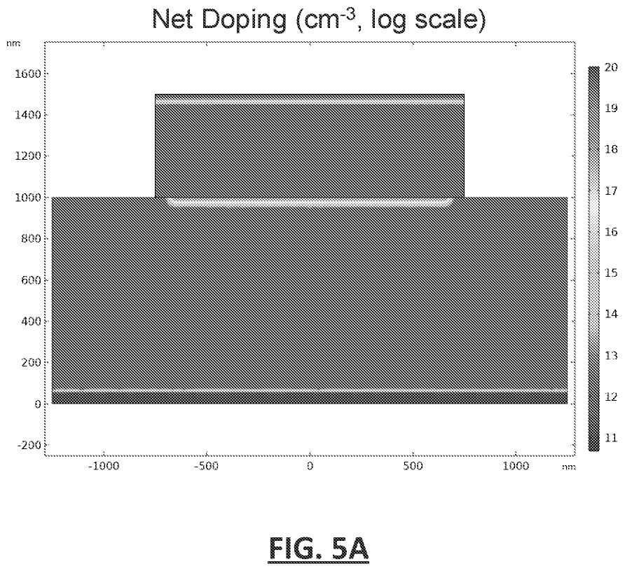

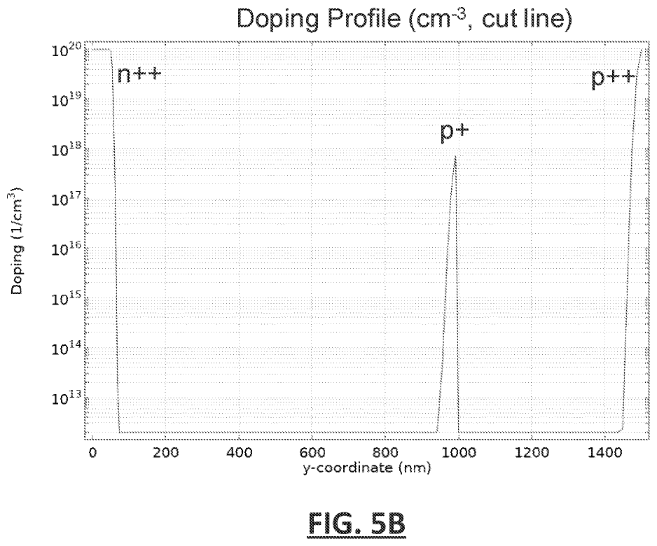

To illustrate, FIG. 5A illustrates a cross-sectional doping diagram of a Mie-APD, according to an example embodiment. In this example, the cross-section illustrates an internal surface of the Mie-APD 400 of FIG. 4 along the x=0 axis. Thus, the top of the figure corresponds to the top surface of the absorption region 420, and the bottom of the figure corresponds to the bottom surface of the material layer 410. As illustrated, the first doping region is illustrated below the top surface of the absorption region 420, the second doping region is illustrated below the top surface of the multiplication region 430 (e.g., just below the absorption region 420), and the third doping region is illustrated above the bottom surface of the material layer 410.

To provide additional context, FIG. 5B illustrates a doping profile of a Mie APD, according to an example embodiment. In the illustrated example, the doping profile is a measure of doping concentration from the bottom surface of the Mie-APD 400 to the top surface of the Mie-APD 400, from right to left. That is, the left side of the figure corresponds to the bottom of FIG. 5A, and the right side of the figure corresponds to the top of FIG. 5A. As such, the third doping region is on the left side and corresponds to the bottom surface of the material layer 410, the second doping region is in the middle and corresponds to the top surface of the multiplication region 430, and the first doping region is on the right side and corresponds to the top surface of the absorption region 420.

Importantly, the illustrated positions, concentrations, and depths of the doping regions are demonstrative and can be different in different configurations of a Mie-APD 400.

For example, while the first doping region is described as “below” or “near” the top surface of the absorption region, the first doping region may also include the top surface. More realistically, the first doping region corresponds to any layer, region, or volume of the absorption region 420 with a doping level having a first doping density (e.g., above a threshold). The first doping density may be doped between 1·10¹⁴ to 1·10²¹, and even into doping degeneracy (if the semiconducting material is silicon). The doping may be p type or n type. The first doping region is generally p++ or n++, indicating doping densities above 1·10¹⁸, but could be other doping densities. The depth of the first doping region may be between 0 nm and 300 nm (when measured from a top surface of the absorption region 420). Additionally, the depth of the first doping region may be defined as a percentage of the absorption region such as, e.g., 1%, 2%, 3%, 5%, 10%, etc. of the total thickness of the absorption region 420.

For example, while the second doping region is described as “below” or “near” the top surface of the multiplication region, the second doping region may also include the top surface of the multiplication region 430. More realistically, the second doping region corresponds to any layer, region, or volume of the multiplication region 430 with a doping level having a second doping density (e.g., above a threshold). The second doping density may be doped between 1·10¹⁴ to 1·10²¹. The doping may be p type or n type. The second doping region is generally p-or n-, indicating doping densities between 1·10¹⁴ and 1·10¹⁸ (if the material is silicon), but could be other doping densities. Additionally, the doping type of the second doping region is typically the same as the first doping region but is several orders of magnitude less. The depth of the second doping region may be between 0 nm and 300 nm (when measured from a top surface of the multiplication region 430). Additionally, the depth of the second doping region may be defined as a percentage of the multiplication region 430 and/or material layer 410 region such as, e.g., 1%, 2%, 3%, 5%, 10%, etc. of the total thickness of the absorption region and/or material layer.

For example, while the third doping region is described as “above” or “near” the bottom surface of the material layer 410, the third doping region may also include the bottom surface of the material layer 410. More realistically, the third doping region corresponds to any layer, region, or volume of the material layer 410 with a doping level having a third doping density (e.g., above a threshold). The third doping density may be doped between 1·10¹⁴ to 1·10²¹, and even into doping degeneracy (if the semiconducting material is silicon). The doping may be p type or n type. The third doping region is generally p++ or n++, indicating doping densities above 1·10¹⁸, but could be other doping densities. Additionally, the doping type of the third doping region is typically the opposite of the first doping region (e.g., one is p++ while the other is n++). The depth of the third doping region may be between 0 nm and 300 nm (when measured from a top surface of the multiplication region 430). Additionally, the depth of the third doping region may be defined as a percentage of the multiplication region 430 and/or material layer 410 region such as, e.g., 1%, 2%, 3%, 5%, 10%, etc. of the total thickness of the absorption region and/or material layer.

In some situations, the doping level of the various doping regions may be selected to target a relative doping between those levels. For instance, the doping of the first doping region relative to the doping of the second doping region may be 10:1, 100:1, or 1,000:1, and the doping of the first doping region relative to the doping of third doping region may be 1:1. Other examples are possible.

The doping levels of the first, second, and third doping regions are selected to establish the desired electric field strengths in the Mie-APD.

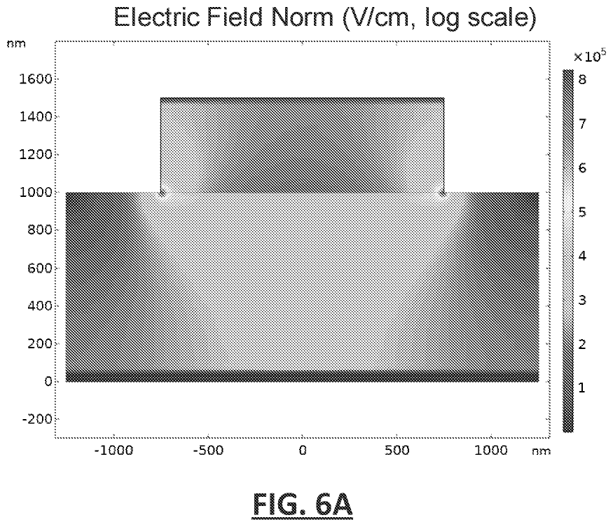

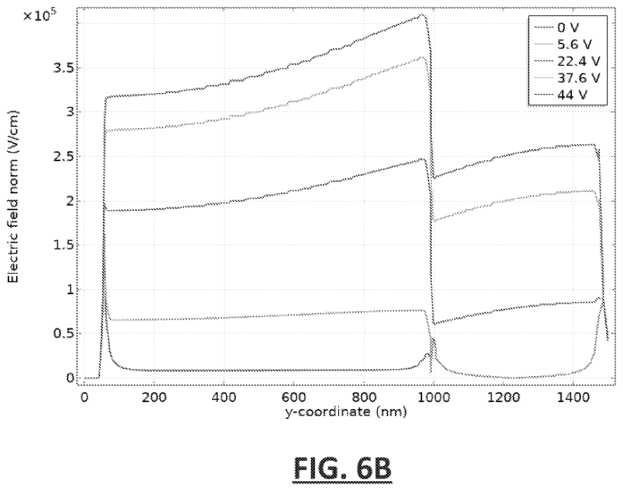

To illustrate, FIG. 6A illustrates a cross-sectional electrical-field diagram of a Mie-APD, according to an example embodiment. In this example, the cross-section illustrates an internal surface of the Mie-APD 400 of FIG. 4 along the x=0 axis. Thus, the top of the figure corresponds to the top surface of the absorption region 420, and the bottom of the figure corresponds to the bottom surface of the material layer 410. As such, the first doping region is illustrated at the top of the diagram, the second doping region in the middle of the diagram, and the third doping region at the bottom of the diagram. In the illustration, the color at each point in the diagram corresponds to the electric field at that point in the Mie-APD 400. At a high level, the electric field in the absorption region 420 (the drift field) is lower than the electric field of the multiplication region 430 (the ionization field).

To provide additional context, FIG. 6B illustrates an electric field profile of a Mie APD, according to an example embodiment. In the illustrated example, the electric field profile is a measure of electric field from the bottom surface of the Mie-APD 400 to the top surface of the Mie-APD 400, from right to left. That is, the left side of the figure corresponds to the bottom of FIG. 6A, and the right side of the figure corresponds to the top of FIG. 6A. As such, the third doping region is on the left side and corresponds to the bottom surface of the material layer 410, the second doping region is in the middle and corresponds to the top surface of the multiplication region 430, and the first doping region is on the right side and corresponds to the top surface of the absorption region 420.

As shown, the electric field strength is highest in the multiplication region (e.g., ionization field strength). The ionization field strength is higher than the electric field strength in the absorption region (e.g., drift field strength). The drift field strength is configured to cause generated carriers to travel from the absorption region to the multiplication region without avalanche, and the ionization field strength is configured to cause avalanche multiplication in the multiplication region as they travel to a contact at the bottom of the material layer.

By varying the doping levels and depths, the corresponding electric fields would change. When fabricating the Mie-APD 400, one may select the doping levels to target the appropriate electric field. In other words, overall, as described above, the doping profile, material, structure (e.g., shape, size, etc.) and biasing of the Mie-APD affect the electric field strengths within the Mie-APD. As such, one or more of these parameters can be tuned to affect carrier generation within the Mie-APD.

### Fabrication

The structure of the Mie-APD (e.g., Mie-APD 400) can be defined using traditional semiconductor lithography techniques. For instance, a combination of photo-resist application, photo-resist patterning with optical lithography and/or electron-beam lithography, and etching can be utilized to fabricate the Mie photo sensor. In this way, the fabrication process can remove defined portions of the n-type gallium arsenide leaving behind individual mesas. Subsequent processing steps can create contacts to the Mie photo sensor 200 (not pictured). The contacts can be ohmic, Schottky, p-n, p-i-n, etc., and the device may have conducting areas to electrically access the contacts.

In terms of generating the desired doping profiles, several processes are possible. For instance, the doping can be formed using ion-implantation. In another example, the Mie-APD can be fabricated using a combination of etching and epitaxial techniques. For instance, a material layer may be fabricated, and an epitaxial technique may be used to create a higher level of doping on top of the material region to form the multiplication region. In turn, the absorption region may be grown on top of the absorption region, and a high-density region may be grown on top of the absorption region. The various shapes can be selected and generated using etching techniques. In other words, the Mie-APD may be a grown planar structure and etching is used to select its geometry.

Overall, the Mie-APD is a single device formed using any of number standard semiconductor fabrication techniques.

### Additional Design Considerations

In some situations, the Mie-APD may designed to normalize one or more electric field profiles internal to the Mie-APD. To expand, recall the electric field profiles of a Mie-APD illustrated in FIG. 6A and FIG. 6B. In this example, the internal electric field has noted “hotspots” near at the interface between the refractive medium, the absorption region, and the multiplication region. The hotspots are illustrated as red dots and indicate the electric field in that region is over twice that of the electric field internal the Mie-APD.

These electric field hotspots are detrimental to operation of the Mie-APD 400 because they aid in inducing disadvantageous surface states and reduce the effectiveness of the absorption and/or multiplication region (e.g., by forcing all generated carriers into a single area or interfering with absorption and carrier generation). As such, the Mie-APD 400 may be configured to reduce the electric field hotspots in a Mie-APD 400. This may occur in several ways.

In a first example, the Mie-APD 400 may include a beveled edge between the absorption region and the material layer. That is, the Mie-APD 400 may have a layer, region, or volume of semiconducting material that slopes from a top surface of the material layer 410 to a side surface of the absorption region 420. The slope may be linear, rounded, etc. The semiconducting material may be the same material as the material layer and/or the absorption region or may a different material.

In a second example, the Mie-APD 400 may include and extended second doping region. To illustrate, recall that to this point the second doping region has been centered between the absorption region 420 and the multiplication region 430, with the second doping region resting underneath the footprint of the absorption region. To reduce the electric field hotspots, the second doping region may be extended laterally such that the layer, region, or volume making up the second doping region is extended outside of the footprint of the absorption region. In other words, rather than the second doping region being confined within the sidewalls of the absorption region, the second doping region can extend beyond the sidewalls of the absorption region. Of course, the shape of the corresponding multiplication region 430 would change to reflect the extended doping region.

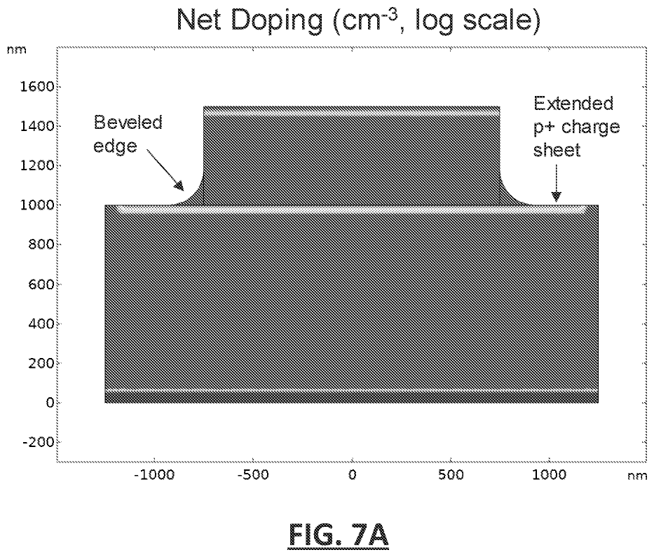

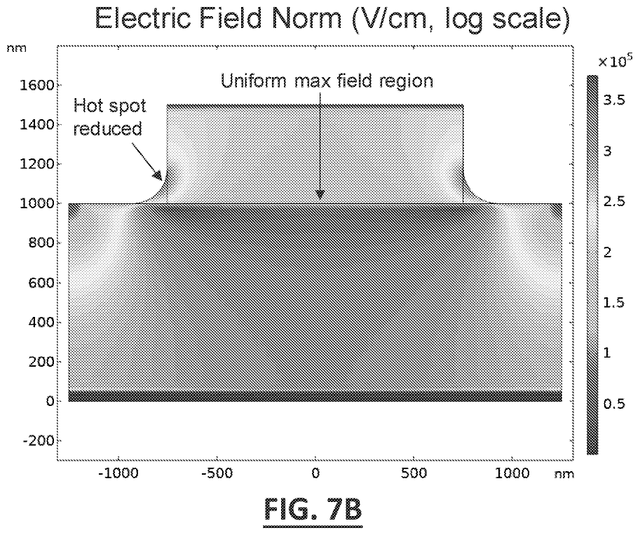

To illustrate, FIG. 7A a cross-sectional doping diagram of a Mie-APD configured to reduce electric field hotspots, according to an example embodiment. In this example, the cross-section illustrates an internal surface of a Mie-APD along an x=0 axis. Again, the top of the figure corresponds to the top surface of an absorption region (e.g., absorption region 420), and the bottom of the figure corresponds to the bottom surface of the material layer (e.g., material layer 410). Notably, the Mie-APD also includes a beveled edge between the material layer and the absorption region. Additionally, as illustrated, the first doping region is illustrated below the top surface of the absorption region. The second doping region is illustrated below the top surface of the multiplication region, and the second doping region extends beyond the sidewalls of the absorption region. The third doping region is illustrated above the bottom surface of the material layer.

To illustrate the effects of these structural and doping changes, FIG. 7B illustrates a cross-sectional electrical-field diagram of a Mie-APD configured to reduce electric field hotspots, according to an example embodiment. In this example, the cross-section illustrates an internal surface of the Mie-APD of FIG. 7A along the x=0 axis. Thus, the top of the figure corresponds to the top surface of the absorption region, and the bottom of the figure corresponds to the bottom surface of the material layer. The beveled edge is still present between the material layer and absorption region. The first doping region is illustrated at the top of the diagram, the second doping region in the middle of the diagram, and the third doping region at the bottom of the diagram. The second doping region is extended beyond the sidewalls of the absorption region. In the illustration, the color at each point in the diagram corresponds to the electric field at that point in the Mie-APD.

At a high level, the electric field in the absorption region still lower than the electric field of the multiplication region. However, of note in this figure the hotspot present in the electric field of FIG. 6A is reduced in FIG. 7B. Additionally, the drift electric field and the ionization electric field are more regular across the length of the Mie-APD relative to FIG. 6A. In turn, the Mie-APD configured to reduce electric field hotspots has higher performance relative to that shown in FIG. 6A.

Additionally, as described above, various applications of a Mie-APD operate the device under reverse bias. Moreover, to achieve some of the useful effects of the device the reverse bias in typical APDs is high, causing an increase in the power necessary to operate such devices. A Mie-APD, due to its vertical structure and increased optical absorption relative to its size, can reduce the overall size of the device. As such, the reverse bias necessary to operate the device asl decreases.

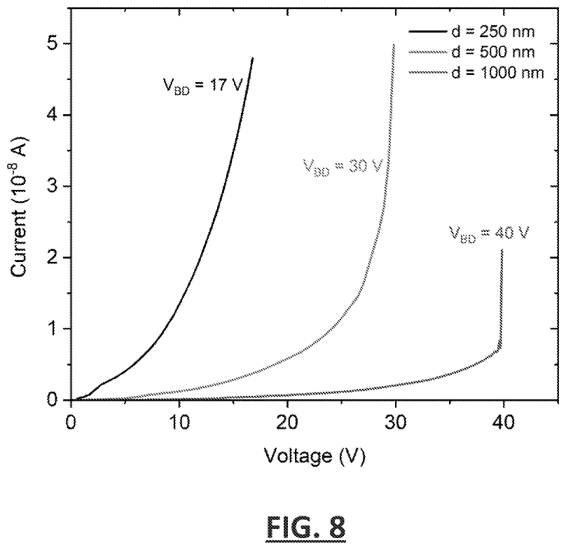

To illustrate, FIG. 8 illustrates a breakdown voltage plot for a Mie-APD, according to an example embodiment. In FIG. 8, the x-axis is the reverse bias applied to a Mie-APD, and the y-axes is the current collected from the device at that reverse bias. Each different line corresponds to a vertical thickness of the device. As illustrated, the breakdown voltage decreases for decreasing thicknesses of a Mie-APD. Decreasing the thickness of the Mie-APD may indicate reducing the vertical thickness any of the absorption region 420, the material layer 410, and the multiplication region 430.

### Unexpected Nature of Mie-APDs

Various advantageous aspects of this avalanche photodiode device, referred to as a Mie-APD (and its array structures such as a Mie-SPAD or Mie-SiPM), derives from its ability to leverage Mie scattering and resonance for improved performance at significantly smaller scales relative to traditional techniques and devices. However, despite the limitations of submicron structures being similar to those observed with regular APDs, Mie-APDs present advantageous characteristics that make their implementation not obvious.

Three core reasons justify this assertion.

First, the resonance localization inherent to the Mie-APD is advantageous and non-obvious. Unlike conventional APDs, Mie-APDs necessitate similar physical depth for efficient photon absorption due to the unique properties of Mie resonance. As demonstrated by its long unused and unforeseen benefits, fabricating devices to harness these structures is not obvious.

Secondly, Mie-APDs allow for layered structures, enabling the creation of the entire doped semiconductor stack epitaxially prior to engaging in lithography and etching processes. This is contrary to traditional APDs, which are largely created in a planar structure and do not harness epitaxial growth stacks.

Thirdly, the fabrication methods employed in creating MIE APDs necessitate etching the resonant structures, which does not occur in traditional APD structures because it is deleterious to their performance. This approach results in the exposure of the whole amplification region's sides at the onset, allowing for surface treatments that were previously unviable in traditional APDs. For example, Mie-APDs can utilize surface oxidation and atomic layer deposition of thin layers, both of which mitigate issues related to surface states present in traditional APDs and consequently decrease noise, enhancing signal quality.

Additionally, the Mie-APD also displays unique behaviors in the realm of Mie scattering, where individual sensor elements and incident light interact at similar size scales. Mie-APDs are designed to produce internal regions with extremely high electric and magnetic fields, an outcome of unique resonance effects observed with high-index dielectrics. This increased generation of photocurrent or voltage contributes to improved photon detection traits, many of which would be unexpected and non-obvious without external filters in traditional APD structures.

Importantly, in terms of size, the Mie-APD's optical cross-section significantly surpasses their geometric one, enabling increased photon utilization with fewer wasted ones (e.g., because those photons would not be absorbed in a traditional APD). Moreover, Mie-APD technology stands out due to the smaller dark current per detection area, due to its smaller depletion-region cross-section compared to other detectors. Additionally, due to their smaller size, the operating regimes (e.g., Geiger mode, multiplication mode) of several APD based structures can be decreased. In turn, their power requirements are greatly diminished.

### V. Mie-APD Arrays

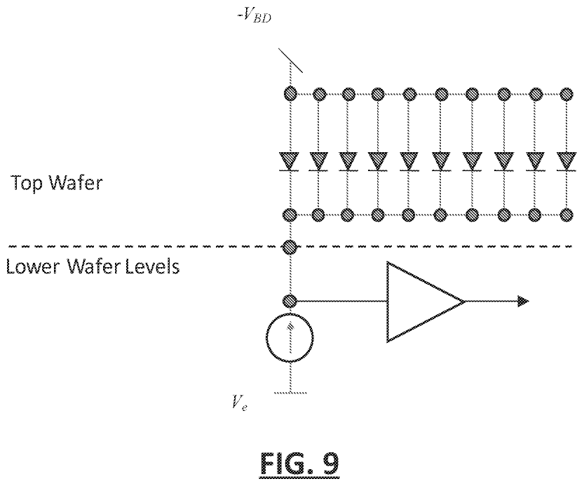

As described above, Mie-APDs can be used in an array to form, e.g., a Mie-SPAD and/or a Mie-SiPM. To illustrate, FIG. 9 illustrates an example circuit diagram for a Mie-SPAD, according to an example embodiment. In the illustrated example, each device on the top-wafer level is a Mie-APD, and devices in the low-wafer level are genericized to indicate control and response logic.

As noted above, a Mie-APD pixels can be fabricated in manner to selectively respond to certain wavelengths and/or polarizations of light by, e.g., controlling one or more of the length, width, height, material, and interface of a Mie-APD pixel. As such, a Mie-APD array may be similarly configured for selectivity. Because of the array structure, the Mie-APD may be configured to selectively respond to multiple wavelengths and/or polarizations. To do so, the Mie-APD array may include one or more pixels configured to respond to a first wavelength and/or a first polarization, and one or more pixels configured to respond to a second wavelength and/or polarization, etc. This concept can be expanded to cover any number of wavelengths and/or polarizations.

### VI. Additional Considerations

In the description above, for purposes of explanation, numerous specific details are set forth in order to provide a thorough understanding of the illustrated system and its operations. It will be apparent, however, to one skilled in the art that the system may be operated without these specific details. In other instances, structures and devices are shown in block diagram form in order to avoid obscuring the system.

Reference in the specification to “one embodiment” or “an embodiment” means that a particular feature, structure, or characteristic described in connection with the embodiment is included in at least one embodiment of the system. The appearances of the phrase “in one embodiment” in various places in the specification are not necessarily all referring to the same embodiment.

Some portions of the detailed descriptions are presented in terms of algorithms or models and symbolic representations of operations on data bits within a computer memory. An algorithm is here, and generally, conceived to be steps leading to a desired result. The steps are those requiring physical transformations or manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise as apparent from the following discussion, it is appreciated that throughout the description, discussions utilizing terms such as “processing” or “computing” or “calculating” or “determining” or “displaying” or the like, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

Some of the operations described herein are performed by a computer physically mounted within a machine. This computer may be specially constructed for the required purposes, or it may comprise a general-purpose computer selectively activated or reconfigured by a computer program stored in the computer. Such a computer program may be stored in a computer-readable storage medium, such as, but is not limited to, any type of disk including floppy disks, optical disks, CD-ROMs, and magnetic-optical disks, read-only memories (ROMs), random access memories (RAMs), EPROMs, EEPROMs, magnetic or optical cards, or any type of non-transitory computer-readable storage medium suitable for storing electronic instructions.

The figures and the description above relate to various embodiments by way of illustration only. It should be noted that from the following discussion, alternative embodiments of the structures and methods disclosed herein will be readily recognized as viable alternatives that may be employed without departing from the principles of what is claimed.

One or more embodiments have been described above, examples of which are illustrated in the accompanying figures. It is noted that wherever practicable similar or like reference numbers may be used in the figures and may indicate similar or like functionality. The figures depict embodiments of the disclosed system (or method) for purposes of illustration only. One skilled in the art will readily recognize from the following description that alternative embodiments of the structures and methods illustrated herein may be employed without departing from the principles described herein.

Some embodiments may be described using the expression “coupled” and “connected” along with their derivatives. It should be understood that these terms are not intended as synonyms for each other. For example, some embodiments may be described using the term “connected” to indicate that two or more elements are in direct physical or electrical contact with each other. In another example, some embodiments may be described using the term “coupled” to indicate that two or more elements are in direct physical or electrical contact. The term “coupled,” however, may also mean that two or more elements are not in direct physical or electrical contact with each other, but yet still co-operate or interact with each other. The embodiments are not limited in this context.

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present), and B is false (or not present), A is false (or not present), and B is true (or present), and both A and B is true (or present).

In addition, the use of the “a” or “an” are employed to describe elements and components of the embodiments herein. This is done merely for convenience and to give a general sense of the system. This description should be read to include one or at least one and the singular also includes the plural unless it is obvious that it is meant otherwise.

Upon reading this disclosure, those of skill in the art will appreciate still additional alternative structural and functional designs for a system and a process for implementing the functionality described herein. Thus, while particular embodiments and applications have been illustrated and described, it is to be understood that the disclosed embodiments are not limited to the precise construction and components disclosed herein. Various modifications, changes, and variations, which will be apparent to those, skilled in the art, may be made in the arrangement, operation, and details of the method and apparatus disclosed herein without departing from the spirit and scope defined in the appended claims.

What is claimed is:

1. A Mie resonance avalanche photodiode (“Mie-APD”) comprising:
an absorber comprising semiconducting material and having a first index of refraction, the semiconducting material comprising a first doped region at a top surface of the absorber, and the absorber configured to generate free carriers within the semiconducting material in response to an electromagnetic perturbation;
a refractive medium surrounding the absorber and having a second index of refraction, the refractive medium and the absorber forming (i) an interface with a boundary index of refraction across the interface that is discontinuous, and (ii) a scattering center configured for generating free carriers via optical absorption and Mie resonance of the electromagnetic perturbation at the scattering center;
a multiplier comprising semiconducting material, the semiconducting material comprising a second doped region at a top surface of the multiplier that is below a bottom surface of the absorber;
a material layer comprising semiconducting material, wherein the material layer comprises the multiplier and a third doped region in the material layer at a bottom surface of the material layer, wherein the first doped region, the second doped region, and the third doped region are doped such that free carriers generated by Mie resonance in the absorber are multiplied to form avalanche carriers via avalanche multiplication in the multiplier; and
one or more electrical contacts comprising a first contact coupled to the absorber and a second contact coupled to the material layer, the one or more electrical contacts configured to sense avalanche carriers generated within the multiplier in response to the electromagnetic perturbation in the absorber.

2. The Mie-APD of claim 1, wherein absorber forms a geometric shape having a set of boundaries, and the scattering center is formed at a geometric boundary of the geometric shape such that the scattering center comprises the semiconducting material of the absorber.

3. The Mie-APD of claim 1, wherein absorber forms a geometric shape having a set of boundaries, and the scattering center is formed at the boundaries of the geometric shape such that the scattering center comprises a portion of the semiconducting material of the absorber.

4. The Mie-APD of claim 1, wherein the semiconducting material of the absorber, the multiplier, and the material layer is silicon, and the first doped region, the second doped region, and the third doped region comprise doped silicon.

5. The Mie-APD of claim 1, wherein the absorber has a height of 100 nm and nm, the height measured in a perpendicular direction relative to the top surface of the material layer.

6. The Mie-APD of claim 1, wherein the absorber has a feature size between 50 nm and 500 nm in a first direction feature size between 50 nm and 500 nm in a second direction, the first direction and the second direction orthogonal to one another and parallel to a top surface of the material layer.

7. The Mie-APD of claim 1, wherein the scattering center is configured to absorb a first wavelength of electromagnetic perturbation, and a size of the scattering center is proportional to the first wavelength of electromagnetic perturbation.

8. The Mie-APD of claim 1, wherein the scattering center is configured to absorb a first polarization of electromagnetic perturbation, and a size of the scattering center is proportional to the first polarization of electromagnetic perturbation.

9. The Mie-APD of claim 1, wherein:
the second index of refraction is a complex index of refraction,
the multiplier has a third index of refraction,
the material layer has a fourth index of refraction,
the second index of refraction is less than the first index of refraction, the third index of refraction, and the fourth index of refraction.

10. The Mie-APD of claim 9, wherein the first index of refraction, the third index of refraction, and the fourth index of refraction are a same index of refraction.

11. The Mie-APD of claim 1, wherein the refractive medium is silicon dioxide.

12. The Mie-APD of claim 1, wherein the refractive medium is liquid crystal.

13. The Mie-APD of claim 1, wherein the refractive medium is a low index of refraction material including any of: air, oil, or water.

14. The Mie-APD of claim 1, wherein the first contact and the second contact are Ohmic contacts.

15. The Mie-APD of claim 1, wherein the second doped region extends beyond a geometric boundary of the absorber.

16. The Mie-APD of claim 1, further comprising a beveled edge between the top surface of the material layer and a side surface of the absorber.

17. The Mie-APD of claim 1, wherein the first doped region and the second doped region are a same type of doping, and the third doping region is a different type doping than the same type of doping.

18. The Mie-APD of claim 1, wherein the first doped region has a higher doping density than the second doped region.

19. The Mie-APD of claim 1, wherein the Mie-APD is a Mie-APD in an array of Mie-APDs forming a Mie Silicon Photomultiplier.

20. The Mie-APD of claim 1, wherein the Mie-APD is a Mie-APD in an array of Mie-APDs forming a Mie Single Photon Avalanche Diode.
